(19) United States
(12) Patent Application Publication
(10) Pub. No.: US 2026/0088068 A1
(43) Pub. Date: Mar. 26, 2026

(54) SEMICONDUCTOR APPARATUS AND METHOD

(71) Applicant: SK hynix Inc., Icheon-si Gyeonggi-do (KR)

(72) Inventor: Hyun Seung KIM, Icheon-si Gyeonggi-do (KR)

(73) Assignee: SK hynix Inc., Icheon-si Gyeonggi-do (KR)

(21) Appl. No.: 19/013,460

(22) Filed: Jan. 8, 2025

(30) Foreign Application Priority Data
Sep. 26, 2024 (KR) 10-2024-0130699

(51) Int. Cl. G11C 7/10

(52) U.S. Cl. CPC G11C 7/1066

(57) ABSTRACT

A semiconductor apparatus includes a first transmission circuit and a second transmission circuit. The first transmission circuit receives a first bank group data through a first bank group global signal line set of a plurality of bank group global signal line sets and outputs the first bank group data on a peripheral circuit global signal line set in accordance with a transmission reference signal when a first data strobe signal is activated. The second transmission circuit receives a second bank group data through a second bank group global signal line set of the plurality of bank group global signal line sets and outputs the second bank group data on the peripheral circuit global signal line set in accordance with the transmission reference signal when a second data strobe signal is activated.

### CROSS-REFERENCES TO RELATED APPLICATION

The present application claims priority under 35 U.S.C. § 119(a) to Korean application number 10-2024-0130699 filed on Sep. 26, 2024, in the Korean Intellectual Property Office, which application is incorporated herein by reference in its entirety.

### BACKGROUND

### 1. Technical Field

Various embodiments generally relate to a semiconductor circuit, including but not limited to read operations in a semiconductor apparatus.

### 2. Related Art

A semiconductor apparatus includes a plurality of unit memory regions, such as memory banks, distributed among a plurality of bank groups to perform read operations and write operations. The plurality of bank groups perform read operations according to a predetermined target operating criterion, such as time interval tCCD (Column to Column Delay).

### SUMMARY

In an embodiment, a semiconductor apparatus may include a first transmission circuit and a second transmission circuit. The first transmission circuit may be configured to receive first bank group data through a first bank group global signal line set of a plurality of bank group global signal line sets and may be configured to output the first bank group data on a peripheral circuit global signal line set in accordance with a transmission reference signal when a first data strobe signal is activated. The second transmission circuit may be configured to receive second bank group data through a second bank group global signal line set of the plurality of bank group global signal line sets and may be configured to output the second bank group data on the peripheral circuit global signal line set in accordance with the transmission reference signal when a second data strobe signal is activated.

In an embodiment, a semiconductor apparatus may include a plurality of bank groups, a plurality of transmission circuits, a command decoding and signal generation circuit, and a delay circuit. The plurality of bank groups may be configured to generate a plurality of data strobe signals upon activation of a plurality of bank group column control signals and may be configured to output the plurality of data strobe signals and a plurality of bank group data. The plurality of transmission circuits may be configured to output the plurality of bank group data transmitted through a plurality of bank group global signal line sets on a peripheral circuit global signal line set at an activation time of a transmission reference signal when a signal received from the plurality of data strobe signals is activated. The command decoding and signal generation circuit may be configured to decode a command and address signal and may be configured to generate a column control signal when a decoding result is identified as a read command. The delay circuit may be configured to output a signal obtained by delaying the column control signal by a predetermined time as the transmission reference signal.

In an embodiment, a method may include receiving first bank group data through a first bank group global signal line set of a plurality of bank group global signal line sets; outputting the first bank group data on a peripheral circuit global signal line set in accordance with a transmission reference signal when a first data strobe signal is activated; receiving second bank group data through a second bank group global signal line set of the plurality of bank group global signal line sets; and outputting the second bank group data on the peripheral circuit global signal line set in accordance with the transmission reference signal when a second data strobe signal is activated.

### BRIEF DESCRIPTION OF THE DRAWINGS

FIG. 1 is a diagram illustrating a semiconductor apparatus according to an embodiment of the present disclosure.

FIG. 2 is a detailed diagram of a semiconductor apparatus according to an embodiment of the present disclosure.

FIG. 3 is a diagram illustrating a bank group column control signal generation circuit according to an embodiment of the present disclosure.

FIG. 4 is a diagram illustrating a first bank group according to an embodiment of the present disclosure.

FIG. 5 is a diagram illustrating a first transmission circuit according to an embodiment of the present disclosure.

FIG. 6 is a diagram illustrating a driving control circuit according to an embodiment of the present disclosure

FIG. 7 is a diagram illustrating a driving circuit according to an embodiment of the present disclosure.

FIG. 8 is a timing diagram during operation of a first transmission circuit according to an embodiment of the present disclosure.

FIG. 9 is a timing diagram during operation of a first transmission circuit according to an embodiment of the present disclosure.

FIG. 10 is a timing diagram during a read operation of a semiconductor apparatus according to an embodiment of the present disclosure.

### DETAILED DESCRIPTION

Embodiments of the present disclosure are described in detail with reference to the accompanying drawings. Specific structural or functional descriptions of embodiments are provided as examples to describe concepts that are disclosed in the present application. Examples or embodiments in accordance with the concepts may be carried out in various forms, and the scope of the present disclosure is not limited to the examples or embodiments described in this specification.

Due to reasons such as physical differences in device characteristics, read operations of a plurality of bank groups may not meet target operating criteria, which hinders increase in operation speed of semiconductors. Various embodiments can improve the operating margin of semiconductors and increase operating speed because read operations of a plurality of bank groups meet target operating criteria.

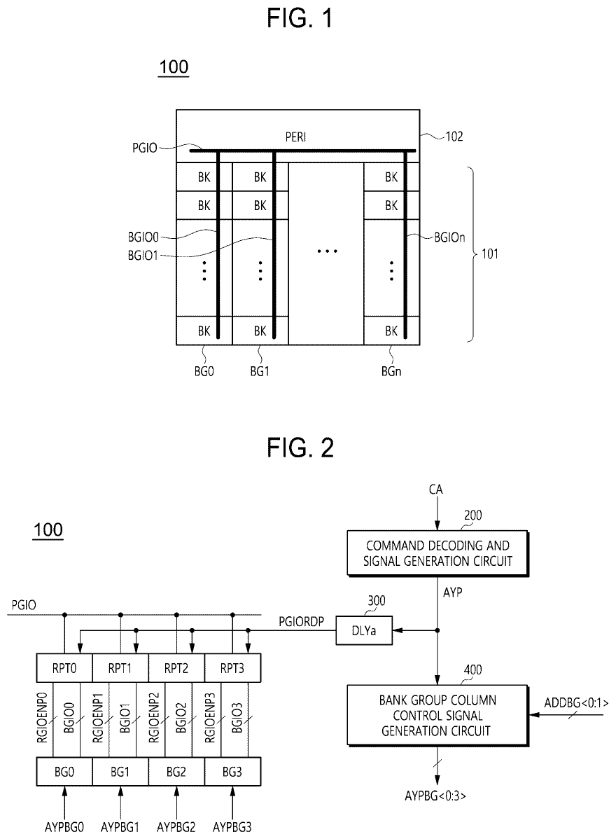

FIG. 1 is a diagram illustrating a semiconductor apparatus 100 according to an embodiment of the present disclosure.

Referring to FIG. 1, the semiconductor apparatus 100 includes a memory region 101, a peripheral circuit region PERI 102, a plurality of bank group global signal line sets BGIO<0:n>, and a peripheral circuit global signal line set PGIO.

The memory region 101 includes a plurality of memory banks BK, and each of the plurality of memory banks BK contains a plurality of bank groups BG0, BG1, . . . BGn.

The peripheral circuit region 102 includes various circuits that interface the memory region 101 with signals external to the semiconductor apparatus 100.

Each of the plurality of bank group global signal line sets BGIO<0:n> include a plurality of signal lines. Each of the plurality of bank group global signal line sets BGIO<0:n> is disposed in one of the plurality of bank groups BG0, BG1, . . . BGn. For example, a first bank group global signal line set BGIO0 is disposed within a bank group BG0 and is coupled with memory banks BK included in the bank group BG0, a second bank group global signal line set BGIO1 is disposed within a bank group BG1 and is coupled with memory banks BK included in the bank group BG1, and an (n+1) bank group global signal line set BGIO<n> is disposed within a bank group BGn and is coupled with memory banks BK included in a bank group BGn.

The peripheral circuit global signal line set PGIO includes a plurality of signal lines. The peripheral circuit global signal line set PGIO is disposed in the peripheral circuit region 102 and is commonly connected with the plurality of bank group global signal line sets BGIO<0:n>.

The time interval tCCD (Column to Column Delay) for the read operation of the plurality of bank groups BG0, BG1, . . . BGn, is described. Among a plurality of bank groups BG0, BG1, . . . BGn, a tCCD value between different bank groups is smaller than a tCCD value within the same bank group. The tCCD value within the same bank group is tCCD-L, where L stands for long, and the tCCD value between different bank groups is tCCD-S, where S stands for short, and tCCD-S is smaller than tCCD-L.

FIG. 2 is a detailed diagram of the semiconductor apparatus 100 according to an embodiment of the present disclosure. FIG. 2 illustrates an example in which the plurality of bank groups BG0, BG1, . . . BGn of FIG. 1 is configured with four bank groups BG0 to BG3.

Referring to FIG. 2, the semiconductor apparatus 100 includes a command decoding and signal generation circuit 200, a delay circuit DLYa 300, a bank group column control signal generation circuit 400, a plurality of bank groups, and a plurality of transmission circuits. The plurality of bank groups includes the first bank group BG0 to the fourth bank group BG3. The plurality of transmission circuits includes a first fourth transmission circuit RPT0 to a fourth transmission circuit RPT3.

The command decoding and signal generation circuit 200, the delay circuit DLYa 300, the bank group column control signal generation circuit 400, and the transmission circuits RPT0 to RPT3 are disposed, for example, in the peripheral circuit region 102 of FIG. 1.

The command decoding and signal generation circuit 200 receives a command and address signal CA and outputs a column control signal AYP. The command decoding and signal generation circuit 200 decodes the command and address signal CA and generate the column control signal AYP when a decoding result is identified as a read command.

The delay circuit 300 outputs a signal that delays the column control signal AYP by a predetermined time delay, which signal is referred to as a transmission reference signal PGIORDP. By outputting the transmission reference signal PGIORDP through the delay circuit 300, each of a plurality of data strobe signals RGIOENP<0:3> is generated at an earlier time relative to each pulse of the transmission reference signal PGIORDP. The word “predetermined” includes, for example, a value for a parameter, such as a time, delay, interval, or voltage level, that is determined prior to use of the parameter in a process or algorithm or an association between elements, such as groups of signal lines, that is identified prior to use of the association. For some embodiments, a value for a parameter or an association between elements is determined before a process or algorithm begins. In other embodiments, a value for a parameter or an association between elements is determined during a process or algorithm but before the parameter or association is used during the process or algorithm.

The bank group column control signal generation circuit 400 receives the column control signal AYP and a plurality of bank group address signals ADDBG<0:1> as inputs and outputs a plurality of bank group column control signals AYPBG<0:3>. The bank group column control signal generation circuit 400 activates one signal, among the plurality of bank group column control signals AYPBG<0:3>, corresponding to a bank group selected by the plurality of bank group address signals ADDBG<0:1> according to the column control signal AYP. To select the first bank group BG0, the second bank group BG1, the third bank group BG2, and the fourth bank group BG3, the plurality of bank group address signals ADDBG<0:1> associated with values 00, 01, 10 and, 11 is input, respectively. The bank group column control signal generation circuit 400 outputs the column control signal AYP as the first bank group column control signal AYPBG0, the second bank group column control signal AYPBG1, the third bank group column control signal AYPBG2, and the fourth bank group column control signal AYPBG3 when the plurality of bank group address signals ADDBG<0:1> are input with values of 00, 01, 10, and 11, respectively.

The bank groups BG0 to BG3 receive the plurality of bank group column control signals AYPBG<0:3> as input and output the plurality of data strobe signals RGIOENP<0:3> and a plurality of bank group data. The bank groups BG0 to BG3 generate the plurality of data strobe signals RGIOENP<0:3> in response to activation of the plurality of bank group column control signals AYPBG<0:3> and output the plurality of data strobe signals RGIOENP<0:3> and the plurality of bank group data. The bank groups BG0 to BG3 synchronize the plurality of bank group data to the plurality of data strobe signals RGIOENP<0:3> and output the plurality of bank group data on the plurality of bank group global signal line sets BGIO<0:3>. The bank groups BG0 to BG3 may be configured similarly to each other.

The first bank group BG0 outputs the first data strobe signal RGIOENP0 and first bank group data when the first bank group column control signal AYPBG0 is enabled. The first bank group BG0 synchronizes the first bank group data to the first data strobe signal RGIOENP0 and outputs the first bank group data on the first bank group global signal line set BGIO0.

The second bank group BG1 outputs the second data strobe signal RGIOENP1 and the second bank group data when the second bank group column control signal AYPBG1 is enabled. The second bank group BG1 synchronizes the second bank group data to the second data strobe signal RGIOENP1 and outputs the second bank group data on the second bank group global signal line set BGIO1.

The third bank group BG2 outputs the third data strobe signal RGIOENP2 and the third bank group data when the third bank group column control signal AYPBG2 is enabled. The third bank group BG2 synchronizes the third bank group data to the third data strobe signal RGIOENP2 and outputs the third bank group data on the third bank group global signal line set BGIO2.

The fourth bank group BG3 outputs the fourth data strobe signal RGIOENP3 and the fourth bank group data when the fourth bank group column control signal AYPBG3 is enabled. The fourth bank group BG3 synchronizes the fourth bank group data to the fourth data strobe signal RGIOENP3 and outputs the fourth bank group data on the fourth bank group global signal line set BGIO3.

The transmission circuits RPT0 to RPT3 are coupled between the plurality of bank group global signal line sets BGIO<0:3> and the peripheral circuit global signal line set PGIO. The transmission circuits RPT0 to RPT3 receive the plurality of bank group data transmitted through the plurality of data strobe signals RGIOENP<0:3>, the transmission reference signal PGIORDP, and the plurality of bank group global signal line sets BGIO<0:3> and output the plurality of bank group data transmitted through the plurality of bank group global signal line sets BGIO<0:3> to the peripheral circuit global signal line set PGIO. The transmission circuits RPT0 to RPT3 output the plurality of bank group data transmitted through the plurality of bank group global signal line sets BGIO<0:3> to the peripheral circuit global signal line set PGIO at an activation time of the transmission reference signal PGIORDP when a signal received from the plurality of data strobe signals RGIOENP<0:3> is activated. The transmission circuits RPT0 to RPT3 may be configured similarly to each other.

The first transmission circuit RPT0 outputs the first bank group data transmitted through the first bank group global signal line set BGIO0 on the peripheral circuit global signal line set PGIO at the activation time of the transmission reference signal PGIORDP when the first data strobe signal RGIOENP0 is activated.

The second transmission circuit RPT1 outputs the second bank group data transmitted through the second bank group global signal line set BGIO1 on the peripheral circuit global signal line set PGIO at the activation time of the transmission reference signal PGIORDP when the second data strobe signal RGIOENP1 is activated.

The third transmission circuit RPT2 outputs the third bank group data transmitted through the third bank group global signal line set BGIO2 on the peripheral circuit global signal line set PGIO at the activation time of the transmission reference signal PGIORDP when the third data strobe signal RGIOENP2 is activated.

The fourth transmission circuit RPT3 outputs the fourth bank group data transmitted through the fourth bank group global signal line set BGIO3 on the peripheral circuit global signal line set PGIO at the activation time of the transmission reference signal PGIORDP when the fourth data strobe signal RGIOENP3 is activated.

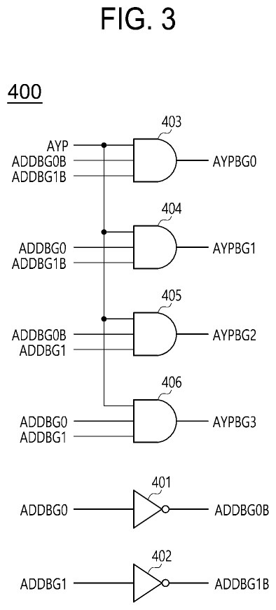

FIG. 3 is a diagram illustrating the bank group column control signal generation circuit 400, for example, as shown in FIG. 2.

Referring to FIG. 3, the bank group column control signal generation circuit 400 combines the plurality of bank group address signals ADDBG<0:1> and the column control signal AYP and outputs the combinations as the plurality of bank group column control signals AYPBG<0:3>. The bank group column control signal generation circuit 400 includes a plurality of logic gates 401 to 406. The first logic gate 401 inverts a first address signal ADDBG0 of the plurality of bank group address signals ADDBG<0:1> and outputs the resulting signal as an inverted first address signal ADDBG0B. The second logic gate 402 inverts a second address signal ADDBG1 of the plurality of bank group address signals ADDBG<0:1> and outputs the resulting signal as an inverted second address signal ADDBG1B. The third logic gate 403 outputs the first bank group column control signal AYPBG0 that is a signal resulting from performing an AND operation on the column control signal AYP, the inverted first address signal ADDBG0B, and the inverted second address signal ADDBG1B. The fourth logic gate 404 outputs the second bank group column control signal AYPBG1 that is a signal resulting from performing an AND operation on the column control signal AYP, the first address signal ADDBG0, and the inverted second address signal ADDBG1B. The fifth logic gate 405 outputs the third bank group column control signal AYPBG2 that is a signal resulting from performing an AND operation on the column control signal AYP, the inverted first address signal ADDBG0B, and the second address signal ADDBG1. The sixth logic gate 406 outputs the fourth bank group column control signal AYPBG3 that is a signal resulting from performing an AND operation on the column control signal AYP, the first address signal ADDBG0, and the second address signal ADDBG1.

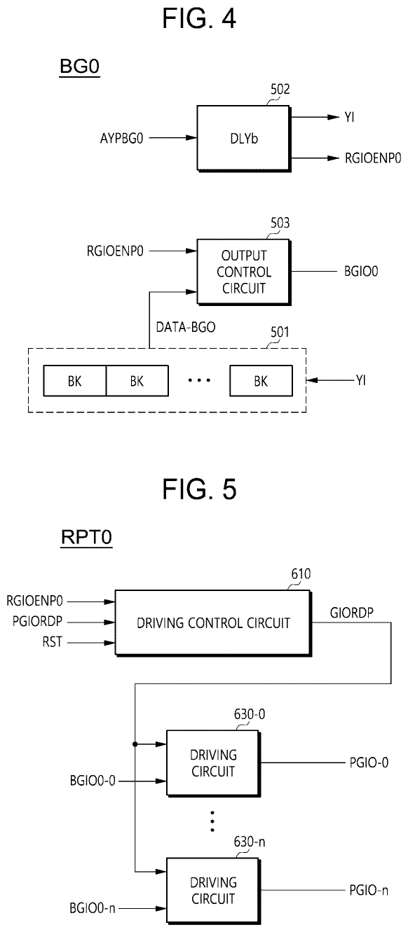

FIG. 4 is a diagram illustrating the first bank group BG0, for example, as shown in FIG. 2. The bank groups BG0 to BG3 may be configured similarly to each other. The configuration of the first bank group BG0 is described with reference to FIG. 4.

Referring to FIG. 4, the first bank group BG0 includes a plurality of memory banks BK 501, a delay circuit DLYb 502, and an output control circuit 503.

The plurality of memory banks 501 outputs a first bank group data DATA-BG0 according to a column selection signal YI.

The delay circuit 502 delays the first bank group column control signal AYPBG0 by different amounts of time to generate the column selection signal YI and the first data strobe signal RGIOENP0. The delay circuit 502 delays the first bank group column control signal AYPBG0 by a first predetermined time to generate the column selection signal YI and delays the first bank group column control signal AYPBG0 by a second predetermined time to generate the first data strobe signal RGIOENP0.

The output control circuit 503 synchronizes the first bank group data DATA-BG0 to the first data strobe signal RGIOENP0 and output the first bank group data DATA-BG0 onto the first bank group global signal line set BGIO0. The output control circuit 503 outputs the first bank group data DATA-BG0 on the first bank group global signal line set BGIO0 when the first data strobe signal RGIOENP0 is enabled.

FIG. 5 is a diagram illustrating the first transmission circuit RPT0, for example, as shown in FIG. 2. The transmission circuits RPT0 to RPT3 may be configured similarly to each other. A configuration of the first transmission circuit RPT0 is described with reference to FIG. 5.

Referring to FIG. 5, the first transmission circuit RPT0 includes a driving control circuit 610 and a plurality of driving circuits 630-0 to 630-n.

The driving control circuit 610 receives the first data strobe signal RGIOENP0, the transmission reference signal PGIORDP, and a reset signal RST and outputs a driving control signal GIORDP. The driving control circuit 610 activates the driving control signal GIORDP at an activation time of the transmission reference signal PGIORDP when the first data strobe signal RGIOENP0 is activated. The driving control circuit 610 initializes the driving control signal GIORDP in response to the reset signal RST.

Each of the plurality of driving circuits 630-0 to 630-n is coupled between a predetermined one of the signal lines BGIO-0 to BGIO-n of the first bank group global signal line set BGIO0 and a predetermined one of the signal lines PGIO-0 to PGIO-n of the peripheral circuit global signal line set PGIO. Each of the plurality of driving circuits 630-0 to 630-n drives a level of a predetermined one of the signal lines PGIO-0 to PGIO-n of the peripheral circuit global signal line set PGIO to match a level of a predetermined one of the signal lines BGIO-0 to BGIO-n of the first bank group global signal line set BGIO0 when the driving control signal GIORDP is activated. The plurality of driving circuits 630-0 to 630-n may be configured similarly to each other.

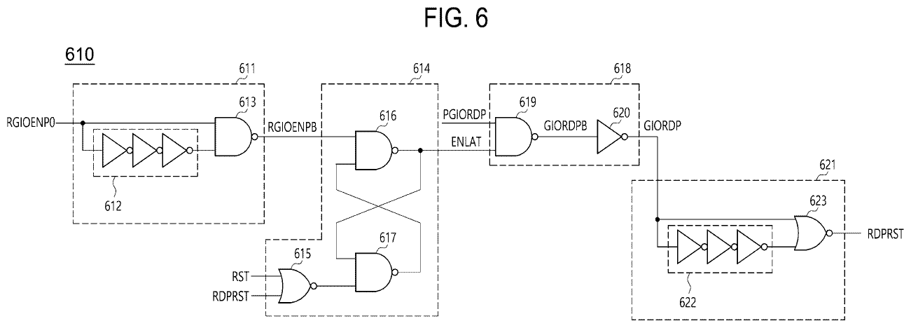

FIG. 6 is a diagram illustrating the driving control circuit 610, for example, as shown in FIG. 5.

Referring to FIG. 6, the driving control circuit 610 includes a first edge detection circuit 611, a latch circuit 614, a driving control signal generation circuit 618, and a second edge detection circuit 621.

The first edge detection circuit 611 detects a rising edge of the first data strobe signal RGIOENP0 and generates an edge detection signal RIOENPB during a predetermined interval at a low logic level. The first edge detection circuit 611 includes a first inverter chain 612 and a first logic gate 613. The first inverter chain 612 inverts and delays the first data strobe signal RGIOENP0 and outputs the result. The first logic gate 613 outputs a result of performing a NAND operation on the first data strobe signal RGIOENP0 and an output of the first inverter chain 612 as the edge detection signal RIOENPB.

The latch circuit 614 outputs a latch signal ENLAT according to the edge detection signal RIOENPB and resets the latch signal ENLAT according to the reset signal RST and a transmission reference reset signal RDPRST. The latch circuit 614 includes a second logic gate 615, a third logic gate 616, and a fourth logic gate 617. The second logic gate 615 outputs a result of performing a NOR operation on the reset signal RST and the transmission reference reset signal RDPRST. The third logic gate 616 and the fourth logic gate 617 sets the latch signal ENLAT according to the edge detection signal RIOENPB and resets the latch signal ENLAT according to an output of the second logic gate 615.

The driving control signal generation circuit 618 generates the driving control signal GIORDP according to the transmission reference signal PGIORDP and the latch signal ENLAT. The driving control signal generation circuit 618 includes a fifth logic gate 619 and a sixth logic gate 620. The fifth logic gate 619 outputs a result of performing a NAND operation on the transmission reference signal PGIORDP and the latch signal ENLAT as an inverted driving control signal GIORDPB. The sixth logic gate 620 inverts the inverted driving control signal GIORDPB and outputs the driving control signal GIORDP.

The second edge detection circuit 621 detects a falling edge of the driving control signal GIORDP and generates the transmission reference reset signal RDPRST during a predetermined interval at a high logic level. The second edge detection circuit 621 includes a second inverter chain 622 and a seventh logic gate 623. The second inverter chain 622 inverts and delays the driving control signal GIORDP and outputs the result. The seventh logic gate 623 outputs a result of performing a NOR operation on the driving control signal GIORDP and an output of the second inverter chain 622 as the transmission reference reset signal RDPRST.

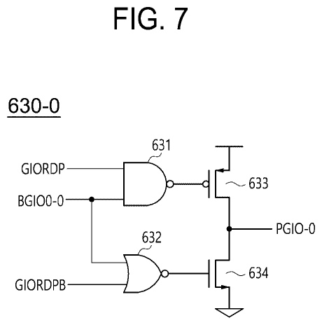

FIG. 7 is a diagram illustrating the driving circuit 630-0, for example, as shown in FIG. 5.

Referring to FIG. 7, the driving circuit 630-0 includes a first logic gate 631, a second logic gate 632, and a driver including a first transistor 633 and a second transistor 634.

The first logic gate 631 outputs a result of performing a NAND operation on the driving control signal GIORDP and the first bank group data transmitted through the signal line BGIO-0 of the first bank group global signal line set BGIO0. The second logic gate 632 outputs a result of performing a NOR operation on the first bank group data transmitted through the signal line BGIO-0 of the first bank group global signal line set BGIO0 and the inverted driving control signal GIORDPB. The driver 633, 634 pulls the signal line PGIO-0 of the peripheral circuit global signal line set PGIO up to a power supply voltage level based on an output of the first logic gate 631 or pulls down the signal line PGIO-0 to a ground voltage level based on an output of the second logic gate 632.

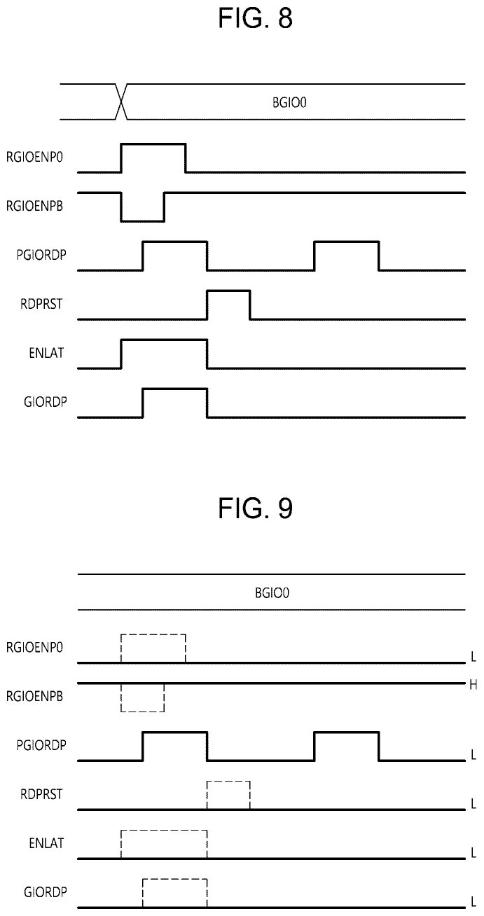

FIG. 8 is a timing diagram during operation of the first transmission circuit RPT0, for example, as shown in FIG. 5 to FIG. 7. FIG. 9 is a timing diagram during another example of operation of the first transmission circuit RPT0 of FIG. 5 to FIG. 7. The operation of the first transmission circuit RPT0 is described with reference to FIG. 5 to FIG. 9.

Referring to FIG. 8, when the first bank group BG0 is selected, the first bank group column control signal AYPBG0 is generated and the first data strobe signal RGIOENP0 is activated at a high logic level.

As the first data strobe signal RGIOENP0 is activated at a high logic level, the first bank group data output from the first bank group BG0 is transmitted through the first bank group global signal line set BGIO0.

The edge detection signal RIOENPB is generated during a predetermined interval at a low logic level according to a rising edge of the first data strobe signal RGIOENP0.

Based on the edge detection signal RIOENPB, the latch signal ENLAT transitions to a high logic level. The transmission reference signal PGIORDP included during an activation interval of the latch signal ENLAT is output as the driving control signal GIORDP.

The first bank group data transmitted to the first bank group global signal line set BGIO0 is transmitted to the peripheral circuit global signal line set PGIO according to an activation time of the driving control signal GIORDP.

The transmission reference reset signal RDPRST is generated during an interval at a high logic level according to a falling edge of the driving control signal GIORDP.

Based on the transmission reference reset signal RDPRST, the latch signal ENLAT transitions to a low logic level.

Referring to FIG. 9, when the second bank group BG1 is selected, the first data strobe signal RGIOENP0 remains disabled at a low logic level.

Because the first data strobe signal RGIOENP0 is at a low logic level, the edge detection signal RIOENPB remains at a high logic level, and because the edge detection signal RIOENPB is at a high logic level, the latch signal ENLAT remains at a low logic level.

Because the latch signal ENLAT is at a low logic level, the driving control signal GIORDP remains low regardless of the transmission reference signal PGIORDP.

Because the driving control signal GIORDP is at a low logic level, the first bank group global signal line set BGIO0 remains at its previous level.

Data from the first bank group global signal line set BGIO0 is transferred to the peripheral circuit global signal line set PGIO while the first data strobe signal RGIOENP0 is enabled at a high logic level.

The first to fourth bank groups BG<0:3> are subject to signal processing-related skew due to various physical influences, including differences in device characteristics. For example, the time at which the first bank group BG0 generates the first data strobe signal RGIOENP0 in response to the first bank group column control signal AYPBG0 and the time at which the fourth bank group BG3 generates the fourth data strobe signal RGIOENP3 in response to the fourth bank group column control signal AYPBG3 should ideally coincide, however, a time difference results in actual circumstances. When the data of the plurality of bank group global signal line sets BGIO<0:3> is transmitted to the peripheral circuit global signal line set PGIO based on the plurality of data strobe signals RGIOENP<0:3>, target tCCD-S for a read operation may not be met between different bank groups.

The transmission reference signal PGIORDP of the present disclosure is generated according to the column control signal AYP independently of the first to fourth bank groups BG<0:3> and provided at the same time, commonly to the first to fourth bank groups BG<0:3>.

When that data from the plurality of bank group global signal line sets BGIO<0:3> is transmitted to the peripheral circuit global signal line set PGIO based on the driving control signal GIORDP that has the same timing as the transmission reference signal PGIORDP, embodiments according to the present disclosure may have the same timing as the data output from the first to the fourth bank group BG<0:3> to the peripheral circuit global signal line set PGIO. Thus, the target delay tCCD-S for the read operation between the different bank groups can be met.

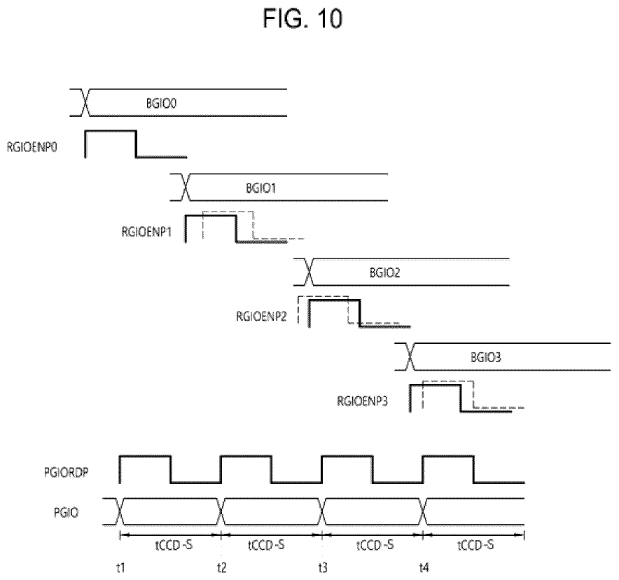

FIG. 10 is a timing diagram during a read operation of the semiconductor apparatus 100 according to an embodiment of the present disclosure. FIG. 10 is an example in which sequential read commands for each of the first to fourth bank groups BG<0:3> are input.

A system external to the semiconductor apparatus 100 provides the semiconductor apparatus 100 with read commands for each of the first to fourth bank groups BG<0:3> at intervals of tCCD-S.

In accordance with the read commands for each of the first to fourth bank groups BG<0:3>, the first to fourth bank group column control signals AYPBG<0:3> are generated, and the first to fourth data strobe signals RGIOENP<0:3> are generated in accordance with the first to fourth bank group column control signals AYPBG<0:3>.

At least one of the first to fourth data strobe signals RGIOENP<0:3> is generated according to timing (solid line) different from target timing (dotted line).

The data of the first to fourth bank groups BG<0:3> is sequentially transmitted to the plurality of bank group global signal line sets BGIO<0:3> based on the rising edges of the first to fourth data strobe signals RGIOENP<0:3>.

At first time t1 corresponding to a first rising edge of the transmission reference signal PGIORDP, data of the first bank group global signal line set BGIO0 is transmitted on the peripheral circuit global signal line set PGIO.

At second time t2 corresponding to a second rising edge of the transmission reference signal PGIORDP, data of the second bank group global signal line set BGIO1 is transmitted on the peripheral circuit global signal line set PGIO.

At third time t3 corresponding to a third rising edge of the transmission reference signal PGIORDP, data of the third bank group global signal line set BGIO2 is transmitted on the peripheral circuit global signal line set PGIO.

At fourth time t4 corresponding to a fourth rising edge of the transmission reference signal PGIORDP, data of the fourth bank group global signal line set BGIO3 is transmitted on the peripheral circuit global signal line set PGIO.

The transmission reference signal PGIORDP of the present disclosure is generated at an interval substantially equal to an input period of the column control signal AYP and is provided substantially simultaneously to each of the first to fourth bank groups BG<0:3> without a time difference, such that the each of the intervals between the first time t1 and the fourth time t4 may meet a target value for tCCD-S.

Concepts are disclosed in conjunction with examples and embodiments. Those skilled in the art will understand that various modifications, additions, combinations, and substitutions are possible without departing from the scope and technical concepts of the present disclosure. The embodiments disclosed in the present specification should be considered from an illustrative standpoint and not a restrictive standpoint. Therefore, the scope of the present disclosure is not limited to the provided descriptions. All changes within the meaning and range of equivalency of the claims are included within their scope.

What is claimed is:

1. A semiconductor apparatus comprising:
a first transmission circuit configured to receive first bank group data through a first bank group global signal line set of a plurality of bank group global signal line sets and configured to output the first bank group data on a peripheral circuit global signal line set in accordance with a transmission reference signal when a first data strobe signal is activated; and
a second transmission circuit configured to receive second bank group data through a second bank group global signal line set of the plurality of bank group global signal line sets and configured to output the second bank group data on the peripheral circuit global signal line set in accordance with the transmission reference signal when a second data strobe signal is activated.

2. The semiconductor apparatus of claim 1, wherein the first transmission circuit comprises:
a driving control circuit configured to activate a driving control signal at an activation time of the transmission reference signal when the first data strobe signal is activated; and
a plurality of driving circuits configured to drive, upon activation of the driving control signal, a logic level of a predetermined signal line of the peripheral circuit global signal line set to a logic level of a predetermined signal line of the first bank group global signal line set.

3. The semiconductor apparatus of claim 2, wherein the driving control circuit comprises:
a first edge detection circuit configured to detect a rising edge of the first data strobe signal to generate an edge detection signal during a predetermined interval at a low logic level;
a latch circuit configured to set a latch signal according to the edge detection signal; and
a driving control signal generation circuit configured to generate the driving control signal according to the transmission reference signal and the latch signal.

4. The semiconductor apparatus of claim 3, wherein the latch circuit is configured to reset the latch signal in accordance with a reset signal and a transmission reference reset signal.

5. The semiconductor apparatus of claim 4, further comprising a second edge detection circuit configured to detect a falling edge of the driving control signal to generate the transmission reference reset signal during a predetermined interval at a high logic level.

6. A semiconductor apparatus comprising:
a plurality of bank groups configured to generate a plurality of data strobe signals upon activation of a plurality of bank group column control signals and configured to output the plurality of data strobe signals and a plurality of bank group data;
a plurality of transmission circuits configured to output the plurality of bank group data transmitted through a plurality of bank group global signal line sets on a peripheral circuit global signal line set at an activation time of a transmission reference signal when a signal received from the plurality of data strobe signals is activated;
a command decoding and signal generation circuit configured to decode a command and address signal and configured to generate a column control signal when a decoding result is identified as a read command; and
a delay circuit configured to output a signal obtained by delaying the column control signal by a predetermined time as the transmission reference signal.

7. The semiconductor apparatus of claim 6, wherein the plurality of bank groups are configured to synchronize the plurality of bank group data to the plurality of data strobe signals and output the plurality of bank group data on the plurality of bank group global signal line sets.

8. The semiconductor apparatus of claim 6, wherein a first bank group of the plurality of bank groups comprises:
a plurality of memory banks configured to output a first bank group data from the plurality of bank group data according to a column selection signal;
a second delay circuit configured to delay a first bank group column control signal of the plurality of bank group column control signals by different amounts of time to generate the column selection signal and a first data strobe signal of the plurality of data strobe signals; and
an output control circuit configured to synchronize the first bank group data to the first data strobe signal and output the first bank group data on a first bank group global signal line set of the plurality of bank group global signal line sets.

9. The semiconductor apparatus of claim 6, wherein a first transmission circuit of the plurality of transmission circuits comprises:
a driving control circuit configured to activate a driving control signal at an activation time of the transmission reference signal when a first data strobe signal of the plurality of data strobe signals is activated; and
a plurality of driving circuits configured to drive, upon activation of the driving control signal, a logic level of a predetermined signal line of the peripheral circuit global signal line set to a logic level of a predetermined one of the plurality of bank group global signal line sets.

10. The semiconductor apparatus of claim 9, wherein the driving control circuit comprises:
a first edge detection circuit configured to detect a rising edge of the first data strobe signal to generate an edge detection signal during a predetermined interval at a low logic level;
a latch circuit configured to set a latch signal according to the edge detection signal; and
a driving control signal generation circuit configured to generate the driving control signal according to the transmission reference signal and the latch signal.

11. The semiconductor apparatus of claim 10, wherein the latch circuit is configured to reset the latch signal in accordance with a reset signal and a transmission reference reset signal.

12. The semiconductor apparatus of claim 11, further comprising a second edge detection circuit configured to detect a falling edge of the driving control signal to generate the transmission reference reset signal during a predetermined interval at a high logic level.

13. The semiconductor apparatus of claim 6, further comprising a bank group column control signal generation circuit configured to activate one signal, among the plurality of bank group column control signals, corresponding to a bank group selected by a plurality of bank group address signals in accordance with the column control signal.

14. The semiconductor apparatus of claim 13, wherein the bank group column control signal generation circuit includes a plurality of logic gates configured to combine the plurality of bank group address signals and the column control signal and output the combinations as the plurality of bank group column control signals.

15. A method comprising:
receiving first bank group data through a first bank group global signal line set of a plurality of bank group global signal line sets;
outputting the first bank group data on a peripheral circuit global signal line set in accordance with a transmission reference signal when a first data strobe signal is activated;
receiving second bank group data through a second bank group global signal line set of the plurality of bank group global signal line sets; and
outputting the second bank group data on the peripheral circuit global signal line set in accordance with the transmission reference signal when a second data strobe signal is activated.
